(19) United States
(12) Patent Application Publication
(10) Pub. No.: US 2008/0149305 A1
(43) Pub. Date: Jun. 26, 2008

(54) Heat Sink Structure for High Power LED Lamp

(76) Inventor: Te-Chung Chen, Zhonghe City (TW)

Correspondence Address: HDSL, 4331 STEVENS BATTLE LANE, FAIRFAX, VA, 22033, US

(21) Appl. No.: 11/614,051

(22) Filed: Dec. 20, 2006

(51) Int. Cl. H05K 7/20

(52) U.S. Cl. 165/80.3; 361/704

(57) ABSTRACT

A heat sink structure for high power LED lamp includes a heat conducting lamp holder, a heat conductor and a heat sink. The heat conducting lamp holder is made of highly heat-conductive material to provide a smooth surface for firmly holding an LED lamp. The heat conductor is made of highly heat-conductive material for linking the heat conducting lamp holder and the heat sink. The heat sink includes a plurality of heat sink fins made of highly heat-conductive material. The plurality of heat sink fins are arranged radially to form a porous center structure with no occluding junction, thereby implementing a heat sink structure which can provide omnidirectional heat dissipating capability and good convection capability to let hot air to rise naturally for high power LED lamps.

### BACKGROUND OF THE INVENTION

1. Field of the Invention

The present invention relates to a heat sink structure for high power LED lamp, and, more particularly, to a heat sink structure having a plurality of heat sink fins arranged radially to form a porous center structure with no occluding junction, thereby implementing a heat sink structure which can provide a omnidirectional heat dissipating capability and a good convection capability to let hot air to rise naturally for high power LED lamps.

2. Description Of The Prior Art

Recently high power LEDs are more and more important in applications such as illumination, traffic lights, ambience lights and backlight modules, etc. due to energy-saving considerations. However, high power LEDs tend to generate more heat, therefore highly efficient heat sink devices are needed to exploit the high brightness and to prolong the life spans of high power LEDs.

Conventional heat sink device comprises heat sink fins made of metal plates and uses a fan to blow the air among the fins to carry heat away. However, due to various concerns such as noise, life span, energy-saving, and size, etc., it is not a welcome option to include fan(s) inside high power LED lamps at present; but fanless heat sink devices could have heat sink fins linked in such configurations (or arranged in such angles) that inappropriately block the natural convection direction of hot air. Please refer to FIG. 6, all the heat sink fins are arranged in parallel with a heat conductor penetrating through and linking every heat sink fin, when all the heat sink fins are arranged horizontally, hot air among the heat sink fins is blocked from flowing in its natural direction, as shown by arrows in FIG. 7. Now refer to FIG. 8, all the heat sink fins are arranged radially with occluding junction, when the axis is placed horizontally, hot air among the heat sink fins the heat sink fins in the lower half is blocked from flowing in its natural direction, as shown by arrows in FIG. 9.

Therefore, the above-mentioned conventional heat sink devices present several shortcomings to be overcome.

In view of the above-described deficiencies of conventional heat sink devices, after years of constant effort in research, the inventor of this invention has consequently developed and proposed a heat sink structure for high power LED lamp in the present invention.

### SUMMARY OF THE INVENTION

The present invention discloses a heat sink structure for high power LED lamp, comprising a heat conducting lamp holder, a heat conductor and a heat sink, the heat conducting lamp holder is made of highly heat-conductive material to provide a smooth surface for firmly holding an LED lamp; the heat conductor is made of highly heat-conductive material for linking the heat conducting lamp holder and the heat sink.

The heat sink comprises a plurality of heat sink fins made of highly heat-conductive material, the plurality of heat sink fins are arranged radially to form a porous center structure with no occluding junction, thereby implementing a heat sink structure which can provide omnidirectional heat dissipating capability and good convection capability to let hot air to rise naturally for high power LED lamps.

### BRIEF DESCRIPTION OF THE DRAWINGS

The drawings disclose an illustrative embodiment of the present invention which serves to exemplify the various advantages and objects hereof, and are as follows:

FIG. 1 is a perspective view of the present invention;

FIG. 2 is a side view of the present invention;

FIG. 3 is a top view of the present invention;

FIG. 4 is a cross-sectional view of the present invention;

FIG. 4A illustratively shows an embodiment of the present invention;

FIG. 5 illustratively shows how hot air rises in the embodiment of the present invention;

FIG. 6 is a perspective view of a conventional heat sink device;

FIG. 7 illustratively shows why hot air is blocked in the conventional heat sink device;

FIG. 8 is a perspective view of another conventional heat sink device; and

FIG. 9 illustratively shows why hot air is blocked in the conventional heat sink device shown in FIG. 8.

### DETAILED DESCRIPTION OF THE PREFERRED EMBODIMENT

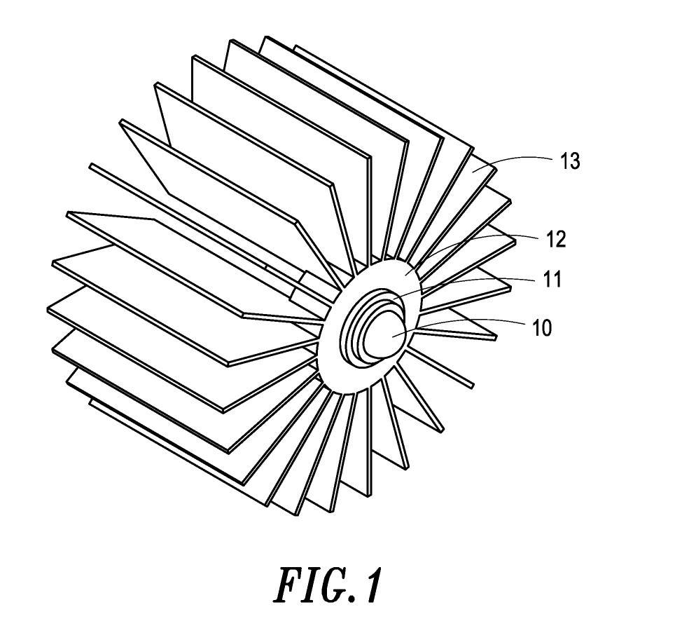

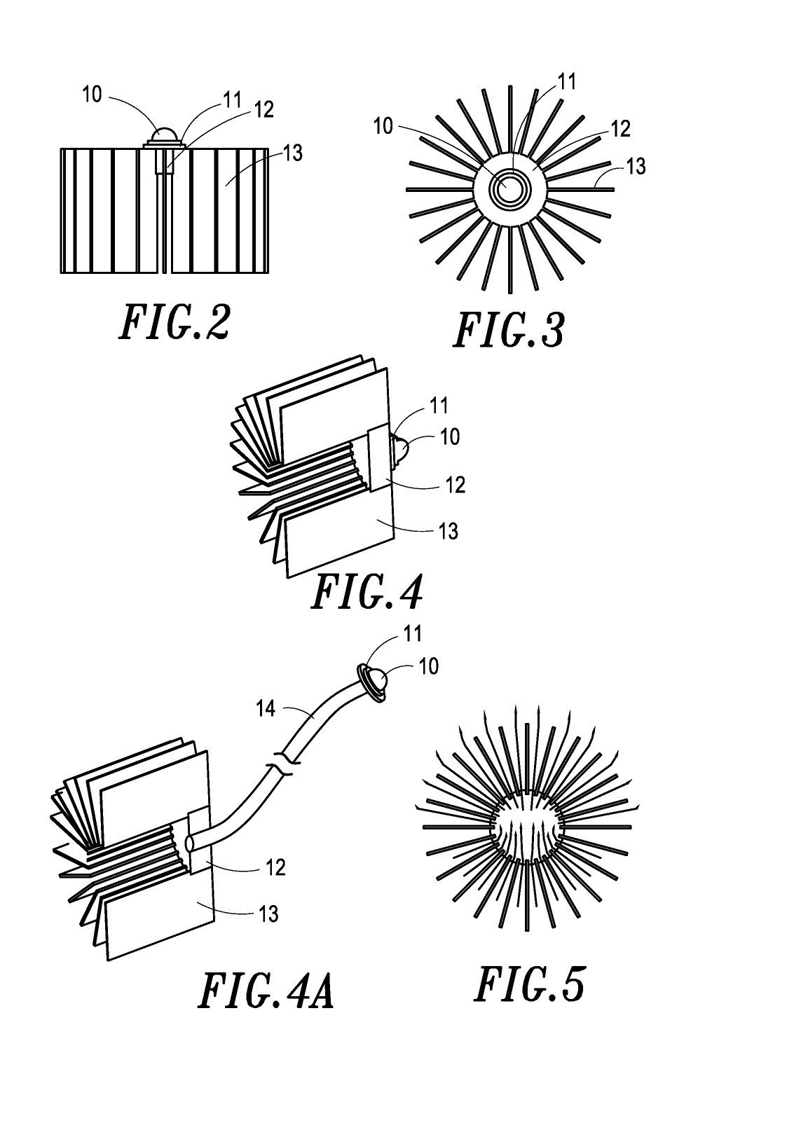

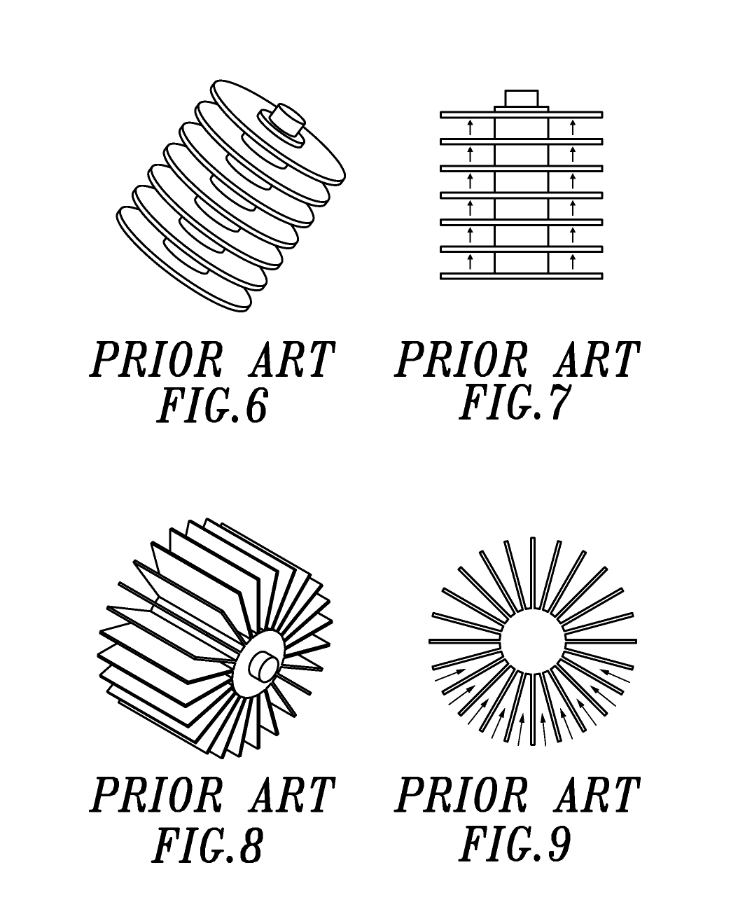

Please refer to FIG. 1, FIG. 2, and FIG. 4 for a heat sink structure for high power LED lamp disclosed in the present invention, the heat sink structure mainly comprises an LED lamp 10, a heat conducting lamp holder 11, a heat conductor 12 and a heat sink 13, wherein the heat conducting lamp holder 11 is made of highly heat-conductive material such as copper, aluminum, zinc, or ceramic, to provide a smooth surface for heat conductive glue or solder (made of tin) to glue the smooth surface and a heat conducting base of the LED lamp 10 together; moreover, the heat conductor 12 is made of highly heat-conductive material, it is mainly used for linking the heat conducting lamp holder 11 and the heat sink 13; the heat sink 13 comprises a plurality of heat sink fins made of highly heat-conductive material and arranged radially, the heat sink fins of the heat sink 13 forms a porous center structure with no occluding junction; furthermore, please refer to FIG. 4A, the heat conductor 12 and the heat conducting lamp holder 11 can be linked by a heat pipe 14.

When the axis surrounded by radially arranged heat sink fins of the heat sink 13 is placed vertically, hot air among the heat sink fins will rise naturally; when the axis is placed horizontally, the hot air will also rise naturally, as shown in FIG. 5, therefore the configuration of heat sink 13 has formed a porous center structure with no occluding junction, thereby implementing a heat sink structure which can provide omnidirectional heat dissipating capability and good convection capability to let hot air to rise naturally for high power LED lamps.

Many changes and modifications in the above described embodiment of the invention can, of course, be carried out without departing from the scope thereof. Accordingly, to promote the progress in science and the useful arts, the invention is disclosed and is intended to be limited only by the scope of the appended claims.

What is claimed is:

1. A heat sink structure for high power LED lamp, comprising:
a heat conducting lamp holder, having a smooth surface for firmly holding a LED lamp;
a heat conductor, used for linking the heat conducting lamp holder and a heat sink; and
a plurality of heat sink fins made of highly heat-conductive material, which is arranged radially to form a porous center structure with no occluding junction.

2. The heat sink structure for high power LED lamp as recited in claim 1, wherein the heat conducting lamp holder, the heat conductor and the heat sink are formed in one piece by die-casting process.

3. The heat sink structure for high power LED lamp as recited in claim 1, wherein the heat sink structure can be a small unit module which can be assembled into a large heat sink structure comprising a plurality of small unit modules.

4. The heat sink structure for high power LED lamp as recited in claim 1, wherein the heat conductor and the heat conducting lamp holder are linked by a heat pipe.
